(19) United States
(12) Patent Application Publication
(10) Pub. No.: US 2025/0192125 A1
(43) Pub. Date: Jun. 12, 2025

(54) DISPLAY PANEL

(71) Applicant: AUO Corporation, Hsinchu City (TW)

(72) Inventors: Hui-Chen HSIAO, Hsinchu City (TW); Shih-Che Lin, Hsinchu City (TW); Yu-Hsun Chiu, Hsinchu City (TW)

(21) Appl. No.: 18/912,639

(22) Filed: Oct. 11, 2024

(30) Foreign Application Priority Data
Dec. 11, 2023 (TW) 112148167

(51) Int. Cl. H01L 25/16; H01L 25/075; H01L 33/62

(52) U.S. Cl. CPC H01L 25/167; H01L 25/0753; H10H 20/857

(57) ABSTRACT

A display panel includes an array substrate and light emitting elements. The array substrate includes a substrate, pad groups, and a retaining wall structure. The substrate has a surface. The surface has a corner, and the corner has two edges connected to each other. The pad groups are disposed on the surface and include a first pad groups located at the corner. The retaining wall structure is disposed on the surface and is located at the corner, and is located between the first pad groups and the two edges of the corner. The retaining wall structure and at least one film layer of the pad groups are formed by patterning the same film layer. The light emitting elements are disposed on the pad groups, respectively.

### CROSS-REFERENCE TO RELATED APPLICATION

This application claims priority to Taiwan Application Serial Number 112148167, filed Dec. 11, 2023, which is herein incorporated by reference in its entirety.

### BACKGROUND

### Field of Invention

The present disclosure relates to a display panel. More particularly, the present disclosure relates to a display panel including a retaining wall structure disposed at a corner of an array substrate.

### Description of Related Art

Micro LED display panels have the advantages of power saving, high efficiency, high brightness and fast response time. However, in the application of frameless panels, the uneven leveling of the photoresist at the corner of the panel easily results in poor etching of the pads at the corner, which in turn leads to a decrease in yield.

### SUMMARY

At least one embodiment of the present disclosure provides a display panel that can improve the uniformity of photoresist at the corner of the display panel to reduce the probability of poor etching of the pads located at the corner, and thereby improve the yield.

The display panel according to at least one embodiment of the present disclosure includes an array substrate and multiple light emitting elements. The array substrate includes a substrate, multiple pad groups, and a first retaining wall structure. The substrate has a surface. The surface has a first corner, and the first corner has a first edge and a second edge connected to the first edge. The pad groups are disposed on the surface and include a first pad groups located at the first corner. The first retaining wall structure is disposed on the surface and located at the first corner, where the first retaining wall structure is located between the first pad groups and the first edge, and is located between the first pad groups and the second edge. The first retaining wall structure and at least one film layer of the pad groups are formed by patterning the same film layer. The light emitting elements are disposed on the pad groups, respectively.

The display panel according to at least another embodiment of the present disclosure includes an array substrate and multiple light emitting elements. The array substrate includes a substrate, multiple pad groups, and a first retaining wall structure. The substrate has a surface. The surface has a first corner, and the first corner has a first edge and a second edge connected to the first edge. The pad groups are disposed on the surface and include a first pad groups located at the first corner. Each of the pad groups includes a first pad receiving a first voltage and a second pad receiving a second voltage different to the first voltage. The first retaining wall structure is disposed on the surface and located at the first corner, where the first retaining wall structure is located between the first pad groups and the first edge, and is located between the first pad groups and the second edge. The first retaining wall structure is electrically connected to the first pads. The light emitting elements are disposed on the pad groups, respectively.

### BRIEF DESCRIPTION OF THE DRAWINGS

FIG. 1A is a schematic top view of a display panel according to at least one embodiment of the present disclosure.

FIG. 1B is an enlarged view of region A in FIG. 1A.

FIG. 1C is a schematic cross-sectional view taken along line a-a′ of FIG. 1B.

FIG. 2A is a schematic top view of a display panel according to at least another embodiment of the present disclosure.

FIG. 2B is an enlarged view of region B in FIG. 2A.

FIG. 2C is a schematic cross-sectional view taken along line b-b′ of FIG. 2B.

FIG. 3A is a schematic top view of a display panel according to at least another embodiment of the present disclosure.

FIG. 3B is an enlarged view of region C in FIG. 3A.

FIG. 3C is a schematic cross-sectional view taken along line c-c′ of FIG. 3B.

FIG. 4A is a schematic top view of a display panel according to at least another embodiment of the present disclosure.

FIG. 4B is an enlarged view of region D in FIG. 4A.

FIG. 4C is a schematic cross-sectional view taken along line d-d′ of FIG. 4B.

### DETAILED DESCRIPTION

In the following description, in order to clearly present the technical features of the present disclosure, the dimensions (such as length, width, thickness, and depth) of elements (such as layers, films, substrates, and areas) in the drawings will be enlarged in unequal proportions. Therefore, the description and explanation of the following embodiments are not limited to the sizes and shapes presented by the elements in the drawings, but should cover the sizes, shapes, and deviations of the two due to actual manufacturing processes and/or tolerances. For example, the flat surface shown in the drawings may have rough and/or non-linear characteristics, and the acute angle shown in the drawings may be round. Therefore, the elements presented in the drawings in this case are mainly for illustration, and are not intended to accurately depict the actual shape of the elements, nor are they intended to limit the scope of patent applications in this case.

Furthermore, the words “about”, “approximately” or “substantially” used in the present disclosure not only cover the clearly stated numerical values and numerical ranges, but also cover those that can be understood by a person with ordinary knowledge in the technical field to which the present disclosure belongs. The permissible deviation range can be determined by the error generated during measurement, and the error is caused, for example, by limitations of the measurement system or process conditions. For example, two objects (such as the plane or traces of a substrate) are “substantially parallel” or “substantially perpendicular,” where “substantially parallel” and “substantially perpendicular,” respectively, mean that parallelism and perpendicularity between the two objects can include non-parallelism and non-perpendicularity caused by permissible deviation ranges.

In addition, “about” may mean within one or more standard deviations of the above values, such as within ±30%, ±20%, ±10%, or ±5%. Such words as “about”, “approximately”, or “substantially” as appearing in the present disclosure may be used to select an acceptable range of deviation or standard deviation according to optical properties, etching properties, mechanical properties, or other properties, rather than applying all of the above optical properties, etching properties, mechanical properties, and other properties with a single standard deviation.

The spatial relative terms used in the present disclosure, such as “below,” “under,” “above,” “on,” and the like, are intended to facilitate the recitation of a relative relationship between one element or feature and another as depicted in the drawings. The true meaning of these spatial relative terms includes other orientations. For example, the relationship between one element and another may change from “below” and “under” to “above” and “on” when the drawing is turned 180 degrees up or down. In addition, spatially relative descriptions used in the present disclosure should be interpreted in the same manner.

It should be understood that while the present disclosure may use terms such as “first”, “second”, “third” to describe various elements or features, these elements or features should not be limited by these terms. These terms are primarily used to distinguish one element from another, or one feature from another. In addition, the term “or” as used in the present disclosure may include, as appropriate, any one or a combination of the listed items in association.

Moreover, the present disclosure may be implemented or applied in various other specific embodiments, and the details of the present disclosure may be combined, modified, and altered in various embodiments based on different viewpoints and applications, without departing from the idea of the present disclosure.

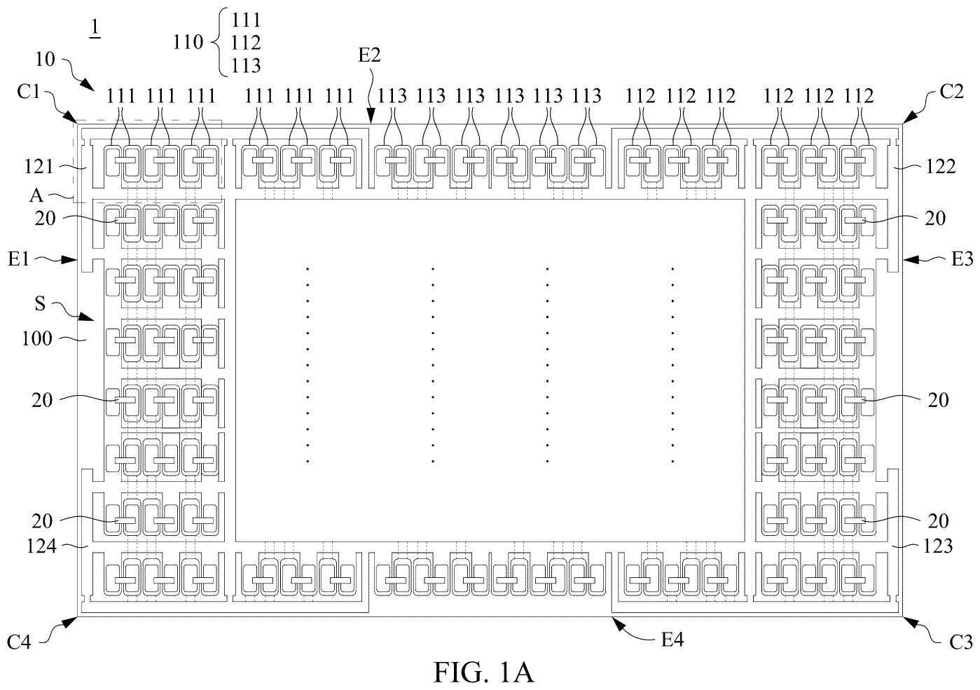

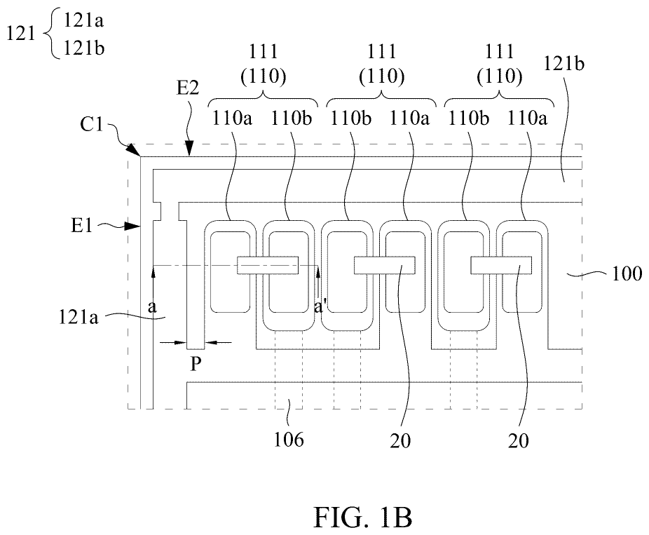

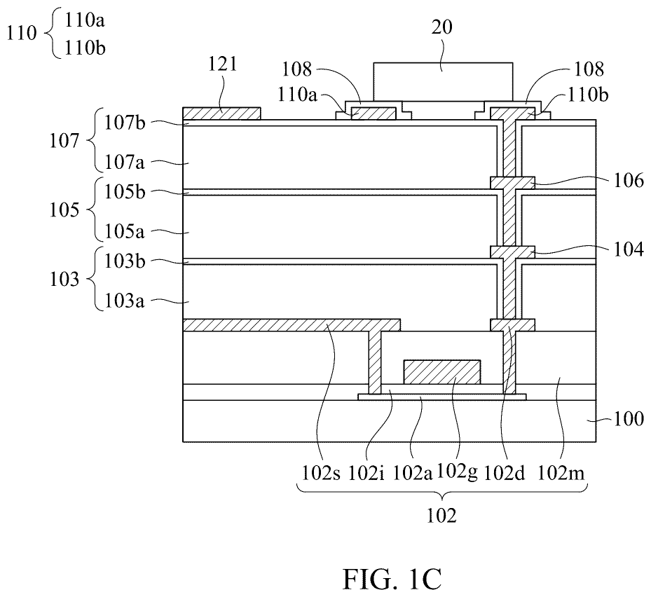

FIG. 1A is a schematic top view of a display panel 1 according to at least one embodiment of the present disclosure. Referring to FIG. 1A, the display panel 1 includes an array substrate 10 and multiple light emitting elements 20. The array substrate 10 includes a substrate 100, a multiple pad groups 110 and a first retaining wall structure 121. The substrate 100 has a surface S, the surface S has a first corner C1, and the first corner C1 has a first edge E1 and a second edge E2 connected to the first edge E1. The pad groups 110 are disposed on the surface S, and include a first pad groups 111 located at the first corner C1. The first retaining wall structure 121 is disposed on the surface S and is located at the first corner C1. The first retaining wall structure 121 is located between the first pad groups 111 and the first edge E1, and is located between the first pad groups 111 and the second edge E2. The first retaining wall structure 121 and at least one film layer of the pad groups 110 are formed by patterning the same film layer. The light emitting elements 20 are disposed on the pad groups 110, respectively.

By disposing the retaining wall structure (e.g., the first retaining wall structure 121) at the corner of the panel, and the retaining wall structure is located between the pad groups at the corner of the panel and two edges of the corner (e.g., the first edge E1 and the second edge E2 of the first corner C1), the uniformity of the photoresist at the corner of the panel can be improved to prevent the thickness of the photoresist from being too thin at the corner of the panel, reducing the probability of poor etching of the pads located at the corner, thereby improving the yield.

Referring to FIG. 1A, the surface S further has a second corner C2, and the second corner C2 has the second edge E2 and a third edge E3 connected to the second edge E2. The pad groups 110 further includes a second pad groups 112 located at the second corner C2 and a third pad groups 113 located between the first pad groups 111 and the second pad groups 112. The array substrate 10 further includes a second retaining wall structure 122, where the second retaining wall structure 122 is disposed on the surface S and is located at the second corner C2. The second retaining wall structure 122 is located between the second pad groups 112 and the second edge E2, and is located between the second pad groups 112 and the third edge E3. The second retaining wall structure 122 and at least one film layer of the pad groups 110 are formed by patterning the same film layer. The first retaining wall structure 121 and the second retaining wall structure 122 do not extend between the third pad groups 113 and the second edge E2. In some embodiments, there is no retaining wall structure between the third pad groups 113 and the second edge E2.

Since the retaining wall structure does not extend between part of the pad group and the edge of the panel, that is, the retaining wall structure is discontinuous, it can avoid the complete closure of the retaining wall structure causing the photoresist at the edge of the panel to be too thick, leading to incomplete exposure and development and causing etching problem.

For example, referring to FIG. 1A, the first retaining wall structure 121 extends from the first corner C1 in a direction parallel to the second edge E2 to a length of about two pixel widths, i.e., a length of six sub-pixel widths, and the second retaining wall structure 122 extends from the second corner C2 in a direction parallel to the second edge E2 to a length of about two pixel widths, i.e., a length of six sub-pixel widths. In some embodiments, the length of the first retaining wall structure 121 and the length of the second retaining wall structure 122 in the direction parallel to the second edge E2 may be both in a range from two to four pixel widths, i.e., a range from six to twelve subpixel widths.

In addition, the first retaining wall structure 121 extends from the first corner C1 in a direction parallel to the first edge E1 to a length of about two pixels lengths, i.e., a length of two sub-pixel lengths, and the second retaining wall structure 122 extends from the second corner C2 in a direction parallel to the third edge E3 to a length of about two pixel lengths, i.e., a length of two sub-pixel lengths. In some embodiments, the length of the first retaining wall structure 121 in the direction parallel to the first edge E1 and the length of the second retaining wall structure 122 in the direction parallel to the third edge E3 may be both in a range from two to four pixel lengths, i.e., a range from two to four sub-pixel lengths.

Similarly, as shown in FIG. 1A, the surface S further has a third corner C3 and a fourth corner C4. The third corner C3 has the third edge E3 and a fourth edge E4 connected to the third edge E3, and the fourth corner C4 has the fourth edge E4 and the first edge E1 connected to the fourth edge E4. The array substrate 10 further includes a third retaining wall structure 123 and a fourth retaining wall structure 124. The third retaining wall structure 123 and the fourth retaining wall structure 124 are disposed on the surface S and located at the third corner C3 and the fourth corner C4, respectively. The third retaining wall structure 123, the fourth retaining wall structure 124, and at least one film layer of the pad groups 110 are formed by patterning the same film layer. The second retaining wall structure 122 and the third retaining wall structure 123 do not extend between part of the pad groups 110 and the third edge E3. The third retaining wall structure 123 and the fourth retaining wall structure 124 do not extend between part of the pad groups 110 and the fourth edge E4. The first retaining wall structure 121 and the fourth retaining wall structure 124 do not extend between part of the pad groups 110 and the first edge E1.

In addition, in some embodiments, the length of the third retaining wall structure 123 and the length of the fourth retaining wall structure 124 in the direction parallel to the fourth edge E4 may be both in a range from two to four pixel widths, i.e., a range from six to twelve subpixel widths. In some embodiments, the length of the third retaining wall structure 123 in the direction parallel to the third edge E3 and the length of the fourth retaining wall structure 124 in the direction parallel to the first edge E1 may be both in a range from two to four pixel lengths, i.e., a range from two to four sub-pixel lengths.

FIG. 1B is an enlarged view of region A in FIG. 1A. Referring to FIG. 1B, the first retaining wall structure 121 includes a first sub-wall 121a and a second sub-wall 121b. The first sub-wall 121a is located between the first edge E1 and the first pad groups 111, and the second sub-wall 121b is located between the second edge E2 and the first pad groups 111. In some embodiments, the first sub-wall 121a and the second sub-wall 121b are arranged in an L-shape. In some embodiments, the first sub-wall 121a is connected to the second sub-wall 121b, i.e., the first sub-wall 121a is connected to the second sub-wall 121b at a location adjacent to the first corner C1 as shown in FIG. 1B. In other embodiments, the first sub-wall 121a may not be connected to the second sub-wall 121b, i.e., there may be a disconnection between the first sub-wall 121a and the second sub-wall 121b. In some embodiments, the disconnection may be located adjacent to the first corner C1.

As shown in FIG. 1B, each of the pad groups 110 includes a first pad 110a and a second pad 110b. The first pad 110a receives a first voltage, and the second pad 110b receives a second voltage different from the first voltage. The first retaining wall structure 121 is electrically connected to the first pads 110a. In some embodiments, the first voltage is a reference voltage (Vss), which may be, for example, a ground voltage, and the second voltage is an operating voltage (Vdd), which may be, for example, a signal voltage obtained by being electrically connected to a signal transmission layer 106.

Referring to FIG. 1B, there is a distance P between the first retaining wall structure 121 and the first pad groups 111, and the distance P is not greater than 50 micrometers. The design of the aforementioned distance range can effectively improve the uniformity of the photoresist at the corner of the panel to prevent the thickness of the photoresist at the corners of the panel from being too thin, which reduces the chance of the pads at the corners being poorly etched, and thus improves the yield.

FIG. 1C is a schematic cross-sectional view taken along line a-a′ of FIG. 1B. Referring to FIG. 1C, the array substrate 10 further includes a switch element 102, a first insulating layer 103, a wiring layer 104, a second insulating layer 105, a signal transmission layer 106, a third insulating layer 107, and a pad protection layer 108. The switch element 102 is disposed on the substrate 100 and includes a active layer 102a, a gate insulating layer 102i, a gate electrode 102g, an interlayer insulating layer 102m, a source electrode 102s, and a drain electrode 102d. The active layer 102a is disposed on the substrate 100, the gate insulating layer 102i is disposed on the active layer 102a, and the gate electrode 102g is disposed on the gate insulating layer 102i.

The interlayer insulating layer 102m is disposed on the gate electrode 102g, and the source electrode 102s and the drain electrode 102d penetrate through the interlayer insulating layer 102m and the gate insulating layer 102i to connect to the active layer 102a. In this embodiment, the gate electrode 102g is disposed above the active layer 102a to form a top-gate thin film transistor, but is not limited thereto. In other embodiments, the gate electrode 102g may be disposed below the active layer 102a to form a bottom-gate thin film transistor. In some embodiments, a buffer layer (not shown) may be provided between the substrate 100 and the active layer 102a.

The first insulating layer 103 is disposed on the source electrodes 102s and the drain electrodes 102d, and the wiring layer 104 is disposed on the first insulating layer 103 and penetrates through the first insulating layer 103 to connect to the switch element 102. The second insulating layer 105 is disposed on the wiring layer 104, and the signal transmission layer 106 is disposed on the second insulating layer 105 and penetrates through the second insulating layer 105 to connect to the wiring layer 104. The third insulating layer 107 is disposed on the signal transmission layer 106, the first pad 110a and the second pad 110b are disposed on the third insulating layer 107, and the second pad 110b penetrates through the third insulating layer 107 to connect to the signal transmission layer 106 in order to receive the second voltage. The pad protection layer 108 is disposed on the first pad 110a and the second pad 110b, and the light emitting element 20 is disposed on the pad protection layer 108.

As shown in FIG. 1C, the first retaining wall structure 121 is formed by patterning the same film layer as the first pads 110a and the second pads 110b of the pad groups 110. In other words, the first retaining wall structure 121 and the pad groups 110 are located on a horizontal plane of approximately the same height, so that the first retaining wall structure 121 can block the photoresist at the corner of the panel, thus effectively improving the uniformity of the photoresist at the corners of the panel, avoiding the thickness of the photoresist at the corner of the panel from being too thin, and reducing the possibility of the pad groups 110 at the corner being poorly etched, and thus improving the yield.

Referring to FIG. 1C, the first insulating layer 103, the second insulating layer 105, and the third insulating layer 107 include organic sub-layers 103a, 105a, 107a and inorganic sub-layers 103b, 105b, 107b, respectively, and the inorganic sub-layers 103b, 105b, 107b are disposed on the organic sub-layers 103a, 105a, 107a, respectively. In some embodiments, the inorganic sub-layers 103b, 105b, 107b are located on the organic sub-layers 103a, 105a, 107a and cover the sidewalls of the organic sub-layers 103a, 105a, 107a. By the aforementioned structural design, moisture penetration into the display panel 1 can be blocked or avoided, thereby preventing the light emitting element 20 and the array substrate 10 from being affected by moisture and thus failing.

The substrate 100 may be a transparent substrate or a non-transparent substrate, and the material of the substrate 100 may be quartz, glass, polymer material, or other suitable material. In some embodiments, the switch element 102, the first insulating layer 103, the wiring layer 104, the second insulating layer 105, the signal transmission layer 106, the third insulating layer 107, the pad groups 110, the first retaining wall structure 121, and the pad protection layer 108 may be formed on the substrate 100 by an deposition process, an inkjet process, a printing process, a coating process, and a lithography process.

In some embodiments, the material of the active layer 102a of the switch element 102 may include silicon semiconductor material (such as polycrystalline silicon, amorphous silicon), oxide semiconductor material, or organic semiconductor material. The materials of the wiring layer 104, the signal transmission layer 106 and the gate electrode 102g, the source electrode 102s and the drain electrode 102d of the switch element 102 may include metals with good conductivity, such as aluminum, molybdenum, titanium, copper and other metals. The materials of the gate insulating layer 102i, the interlayer insulating layer 102m, the first insulating layer 103, the second insulating layer 105 and the third insulating layer 107 may include transparent insulating materials, such as transparent inorganic insulating materials or transparent organic insulating materials. The transparent insulating materials such as silicon oxide, silicon nitride, silicon oxynitride. The transparent organic insulating materials such as polymethyl methacrylate (PMMA), siloxane, polyimide, epoxy.

In some embodiments, the materials of the organic sub-layer 103a of the first insulating layer 103, the organic sub-layer 105a of the second insulating layer 105, and the organic sub-layer 107a of the third insulating layer 107 may include transparent organic insulating materials, such as polymethyl methacrylate, siloxane, polyimide, and epoxy. By placing the aforementioned organic insulating materials between the metal layers of the switch element 102, the wiring layer 104, the signal transmission layer 106, and the pad groups 110 to provide a certain thickness of the insulating layer, the flatness can be increased, and the capacitance between the metal layers can also be reduced, which in turn reduces the circuit loading of the array substrate 10.

The materials of the inorganic sub-layer 103b of the first insulating layer 103, the inorganic sub-layer 105b of the second insulating layer 105, and the inorganic sub-layer 107b of the third insulating layer 107 may include transparent inorganic insulating materials, such as silicon oxide, silicon nitride, and silicon nitride oxide. By placing the aforementioned inorganic insulating materials on the organic sub-layers 103a, 105a, 107a and covering the sidewalls of the organic sub-layers 103a, 105a, 107a, the moisture absorbed by the organic sub-layers 103a, 105a, 107a can be blocked or avoided from penetrating into the display panel 1, thus preventing the light emitting element 20 and the array substrate 10 from being affected by moisture and thus failing.

In some embodiments, the material of the pad protection layer 108 may include indium tin oxide (ITO), indium zinc oxide (IZO), aluminum tin oxide (ATO), aluminum zinc oxide (AZO), indium germanium zinc oxide (IGZO), or other suitable materials. By disposing the pad protection layer 108 on the first pad 110a and the second pad 110b, the first pad 110a and the second pad 110b can be prevented from being exposed to metal diffusion or serious oxidization resulting in abnormal resistance value and affecting the display quality.

The light emitting element 20 may be a light emitting diode (LED), which is, for example, a sub-millimeter light emitting diode (mini LED) or a micro light emitting diode (micro LED, μLED). The micro LED has a thickness less than 10 micrometers, e.g., 6 micrometers. The sub-millimeter LEDs can be categorized into two types: one containing a package and the other not containing a package. The thickness of the sub-millimeter light emitting diode containing the package can be less than 800 micrometers, and the thickness of the sub-millimeter light emitting diode not containing the package may be less than 100 micrometers. In addition, the light emitting element 20 may also be a large size regular light emitting diode (regular LED) other than the sub-millimeter light emitting diode and the micro light emitting diode, so that the light emitting element 20 is not limited to the sub-millimeter light emitting diode or the micro light emitting diode.

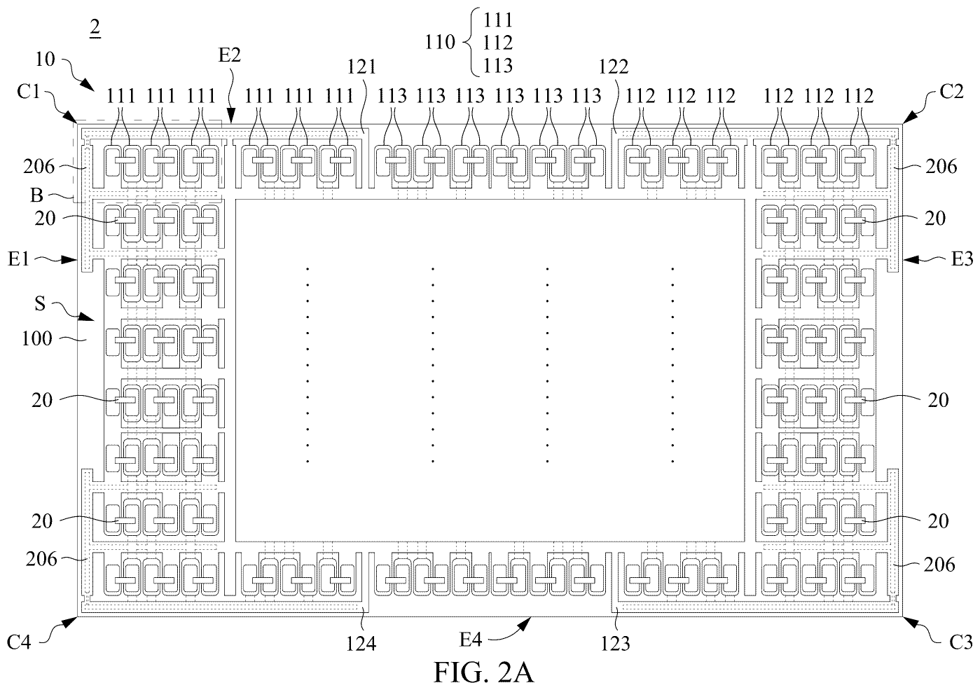

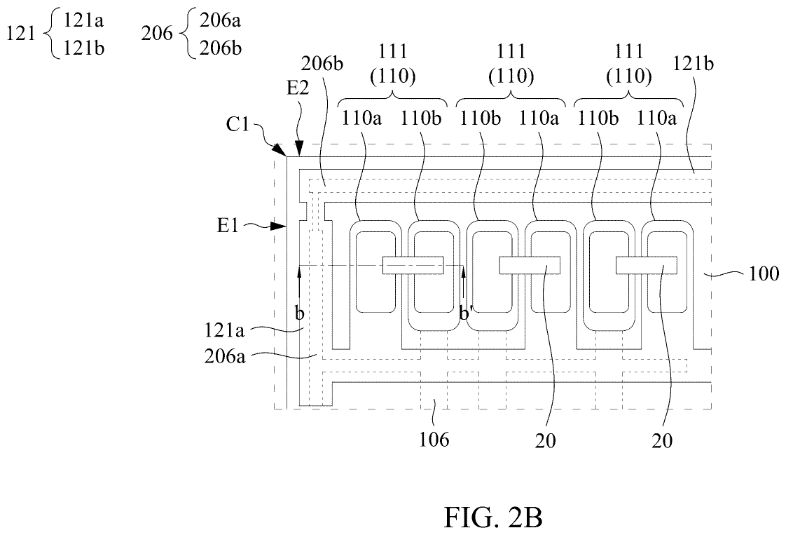

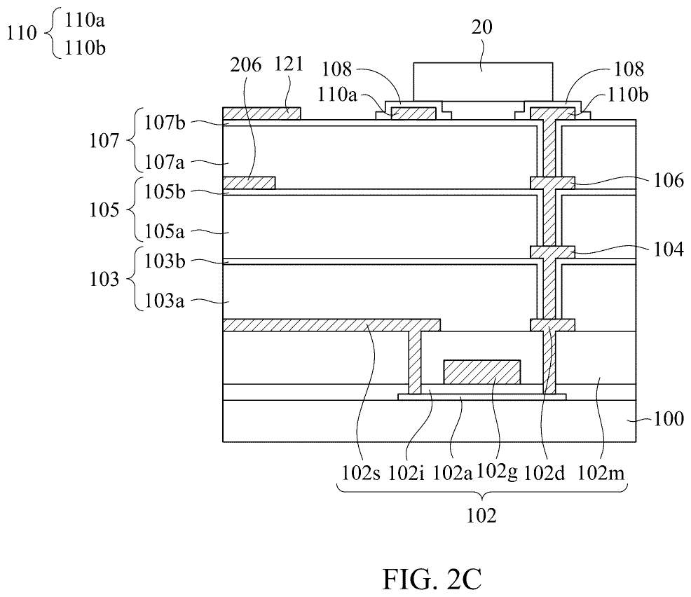

FIG. 2A is a schematic top view of a display panel 2 according to at least another embodiment of the present disclosure. Referring to FIG. 2A, the structures, the materials, the manufacturing processes and the relative positions of most elements in the embodiment of FIG. 2A and the embodiment of FIG. 1A are the same, so the same features are not repeated here. The difference between the embodiment of FIG. 2A and the embodiment of FIG. 1A is that the array substrate 10 of the display panel 2 of FIG. 2A further includes a cushion layer 206.

FIG. 2B is an enlarged view of region B in FIG. 2A. FIG. 2C is a schematic cross-sectional view taken along line b-b′ of FIG. 2B. Referring to FIG. 2B and FIG. 2C, the cushion layer 206 is disposed between the substrate 100 and the first retaining wall structure 121 and overlaps the first retaining wall structure 121 in the normal line of the substrate 100. The cushion layer 206 and at least one film layer of the signal transmission layer 106 are formed by patterning the same film layer.

As shown in FIG. 2B, the cushion layer 206 is electrically connected to the signal transmission layer 106. In addition, the cushion layer 206 includes a first sub-cushion 206a and a second sub-cushion 206b. The first sub-cushion 206a is located between the first edge E1 and the first pad groups 111, and the second sub-cushion 206b is located between the second edge E2 and the first pad groups 111. In some embodiments, the first sub-cushion 206a and the second sub-cushion 206b are arranged in an L-shape. In some embodiments, the first sub-cushion 206a is connected to the second sub-cushion 206b, i.e., as shown in FIG. 2B, the first sub-cushion 206a is connected to the second sub-cushion 206b at a location adjacent to the first corner C1. In other embodiments, the first sub-cushion 206a may not be connected to the second sub-cushion 206b, i.e., there may be a disconnection between the first sub-cushion 206a and the second sub-cushion 206b. In some embodiments, the disconnection may be located adjacent to the first corner C1.

As shown in FIG. 20, the cushion layer 206 and the signal transmission layer 106 are formed by patterning the same film layer. In other words, the cushion layer 206 and the signal transmission layer 106 are located on a horizontal plane of approximately the same height, so that the cushion layer 206 can block the photoresist at the corner of the panel, thus effectively improving the uniformity of the photoresist at the corners of the panel, avoiding the thickness of the photoresist at the corner of the panel from being too thin, and reducing the chance of the signal transmission layer 106 at the corner being poorly etched, and thus improving the yield.

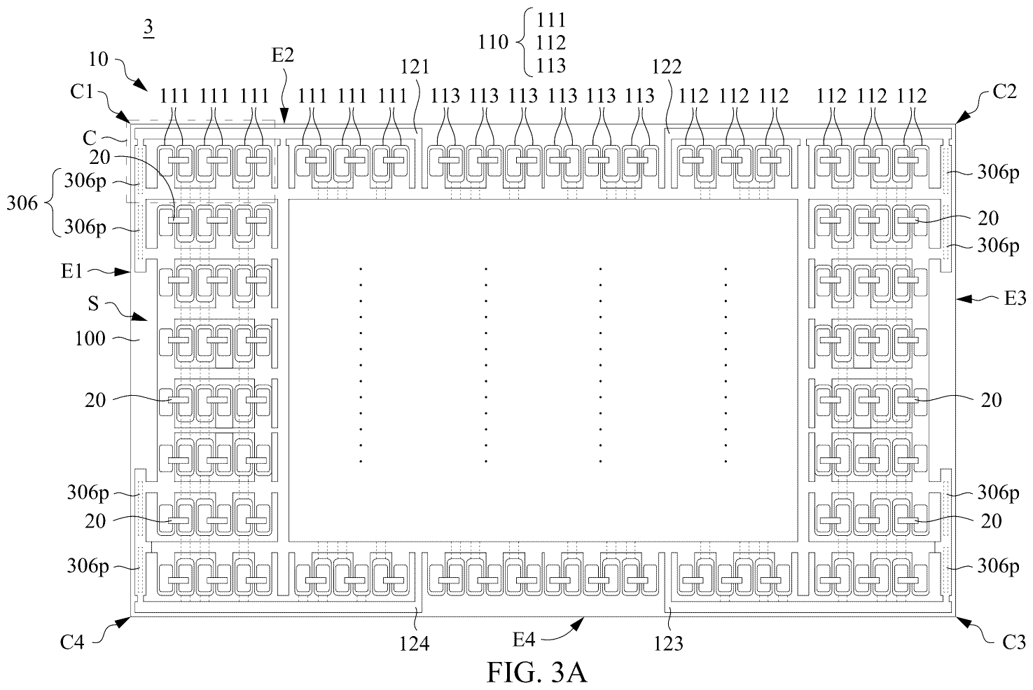

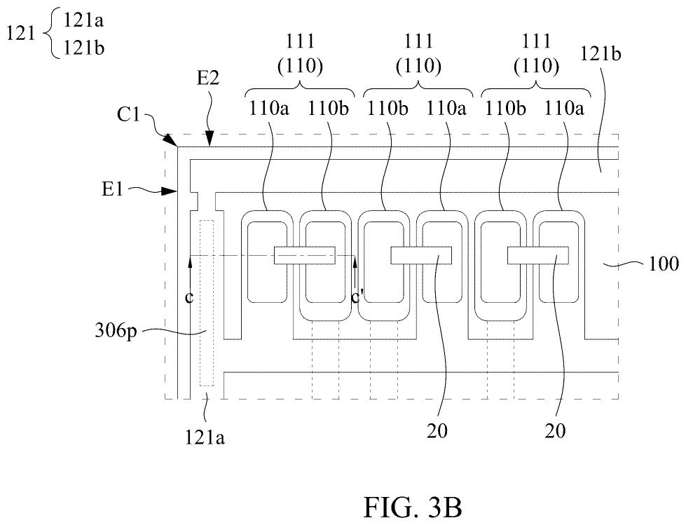

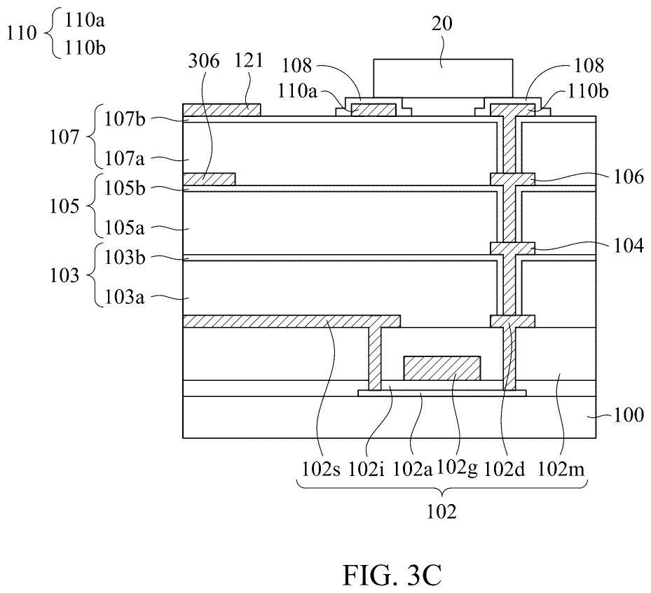

FIG. 3A is a schematic top view of a display panel 3 according to at least another embodiment of the present disclosure. Referring to FIG. 3A, the structures, the materials, the manufacturing processes and the relative positions of most elements in the embodiment of FIG. 3A and the embodiment of FIG. 2A are the same, so the same features are not repeated here. The difference between the embodiment of FIG. 3A and the embodiment of FIG. 2A is that the cushion layer 306 of the display panel 3 of FIG. 3A includes multiple sections 306p, and the sections 306p are electrically floating.

FIG. 3B is an enlarged view of region C in FIG. 3A. FIG. 3C is a schematic cross-sectional view taken along line c-c′ of FIG. 3B. Referring to FIG. 3B and FIG. 3C, the sections 306p are not electrically connected to other layers, that is, the sections 306p are an electrically floating conductive layer that does not receive any signals.

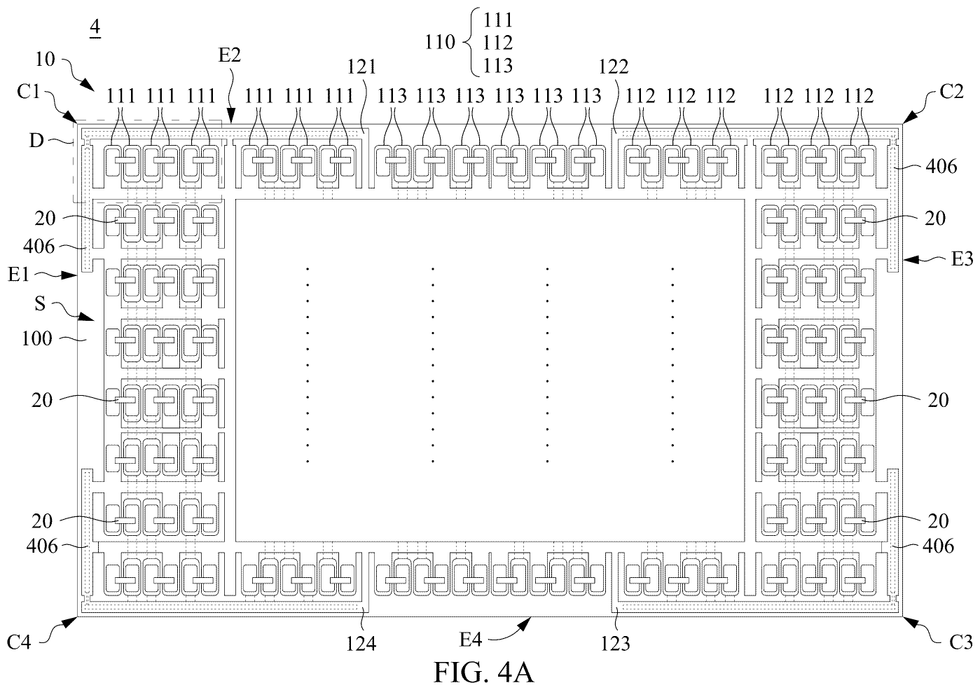

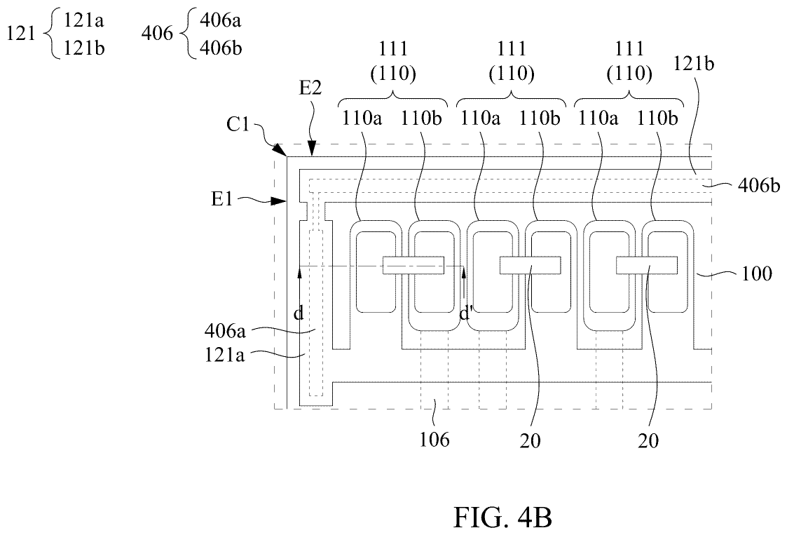

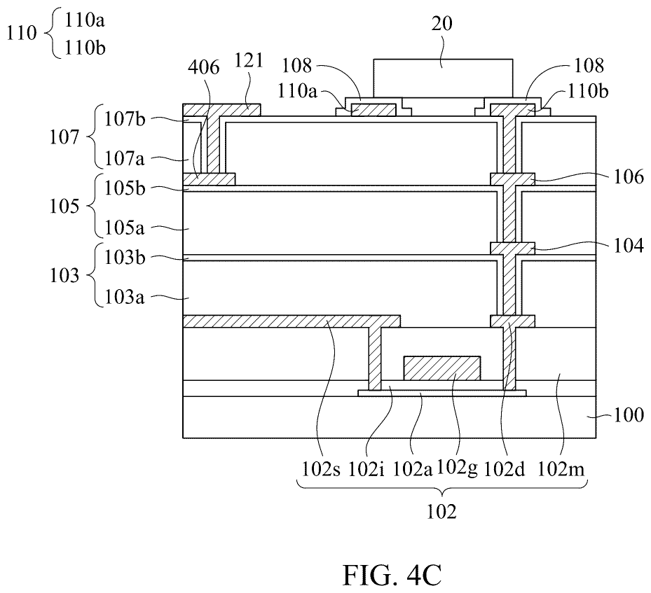

FIG. 4A is a schematic top view of a display panel 4 according to at least another embodiment of the present disclosure. Referring to FIG. 4A, the structures, the materials, the manufacturing processes and the relative positions of most elements in the embodiment of FIG. 4A and the embodiment of FIG. 2A are the same, so the same features are not repeated here. The difference between the embodiment of FIG. 4A and the embodiment of FIG. 2A is that the cushion layer 406 of the display panel 4 in FIG. 4A is electrically connected to the first pads 110a.

FIG. 4B is an enlarged view of region D in FIG. 4A. FIG. 4C is a schematic cross-sectional view taken along line d-d′ of FIG. 4B. Referring to FIG. 4B and FIG. 4C, the first retaining wall structure 121 is electrically connected to the first pads 110a, and the cushion layer 406 is electrically connected to the first retaining wall structure 121, so the cushion layer 406 is electrically connected to the first pads 110a. In addition, the cushion layer 406 includes a first sub-cushion 406a and a second sub-cushion 406b. The relative positions and the connection relationships of the first sub-cushion 406a and the second sub-cushion 406b are similar to that of the first sub-cushion 206a and the second sub-cushion 206b described above in FIG. 2B, so the same features are not repeated here.

With the above-mentioned design of the electrical connection relationship, compared to the cushion layer 206 of the display panel 2 which is electrically connected to the signal transmission layer 106 which has a different voltage from the first retaining wall structure 121, or the cushion layer 306 of the display panel 3 which is electrically floating, the cushion layer 406 of the display panel 4, which is electrically connected to the first retaining wall structure 121, is less susceptible to cause short circuit problems between the cushion layer and the retaining wall structure overlapping each other that receive different voltages due to process steps (such as laser cutting), or unnecessary capacitance due to the electrically floating cushion layer overlaps the retaining wall structure.

In summary, in at least one embodiment of the display panel of the present disclosure, by disposing the retaining wall structure at the corner of the panel, and the retaining wall structure is located between the pad groups at the corner of the panel and two edges of the corner, the uniformity of the photoresist at the corner of the panel can be improved to prevent the thickness of the photoresist from being too thin at the corner of the panel, reducing the probability of poor etching of the pads located at the corner, thereby improving the yield.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims.

What is claimed is:

1. A display panel, comprising:
an array substrate, comprising:
a substrate, having a surface, wherein the surface has a first corner, and the first corner has a first edge and a second edge connected to the first edge;
a plurality of pad groups, disposed on the surface and comprising a first pad groups located at the first corner; and
a first retaining wall structure, disposed on the surface and located at the first corner, wherein the first retaining wall structure is located between the first pad groups and the first edge, and is located between the first pad groups and the second edge, wherein the first retaining wall structure and at least one film layer of the pad groups are formed by patterning the same film layer; and
a plurality of light emitting elements, disposed on the pad groups, respectively.

2. The display panel of claim 1, wherein the first retaining wall structure comprises:
a first sub-wall, located between the first pad groups and the first edge; and
a second sub-wall, located between the first pad groups and the second edge.

3. The display panel of claim 2, wherein the first sub-wall is connected to the second sub-wall.

4. The display panel of claim 1, wherein each of the pad groups comprises:
a first pad, receiving a first voltage; and
a second pad, receiving a second voltage different to the first voltage, wherein the first retaining wall structure is electrically connected to the first pads.

5. The display panel of claim 4, wherein the array substrate further comprises:
a signal transmission layer, disposed between the substrate and the pad groups, and electrically connected to the second pads; and
a cushion layer, disposed between the substrate and the first retaining wall structure, and overlapping the first retaining wall structure in a normal line of the substrate, wherein the cushion layer and at least one film layer of the signal transmission layer are formed by patterning the same film layer.

6. The display panel of claim 5, wherein the cushion layer is electrically connected to the signal transmission layer.

7. The display panel of claim 5, wherein the cushion layer comprises a plurality of sections, and the sections are electrically floating.

8. The display panel of claim 5, wherein the cushion layer is electrically connected to the first pads.

9. The display panel of claim 1, wherein a distance between the first retaining wall structure and the first pad groups is not greater than 50 micrometers.

10. The display panel of claim 1, wherein the surface further has a second corner, and the second corner has the second edge and a third edge connected to the second edge, wherein the pad groups further comprises a second pad groups located at the second corner, wherein the array substrate further comprises a second retaining wall structure disposed on the surface and located at the second corner, wherein the second retaining wall structure is located between the second pad groups and the second edge, and is located between the second pad groups and the third edge, wherein the second retaining wall structure and at least one film layer of the pad groups are formed by patterning the same film layer.

11. The display panel of claim 10, wherein the pad groups further comprises a third pad groups located between the first pad groups and the second pad groups, wherein the first retaining wall structure and the second retaining wall structure do not extend between the third pad groups and the second edge.

12. The display panel of claim 10, wherein the surface further has a third corner and a fourth corner, the third corner has the third edge and a fourth edge connected to the third edge, and the fourth corner has the fourth edge and the first edge connected to the fourth edge, wherein the array substrate further comprises a third retaining wall structure and a fourth retaining wall structure, and the third retaining wall structure and the fourth retaining wall structure are disposed on the surface and located at the third corner and the fourth corner, respectively, wherein the third retaining wall structure, the fourth retaining wall structure, and at least one film layer of the pad groups are formed by patterning the same film layer.

13. A display panel, comprising:
an array substrate, comprising:
a substrate, having a surface, wherein the surface has a first corner, and the first corner has a first edge and a second edge connected to the first edge;
a plurality of pad groups, disposed on the surface and comprising a first pad groups located at the first corner, wherein each of the pad groups comprises a first pad receiving a first voltage and a second pad receiving a second voltage different to the first voltage; and
a first retaining wall structure, disposed on the surface and located at the first corner, wherein the first retaining wall structure is located between the first pad groups and the first edge, and is located between the first pad groups and the second edge, wherein the first retaining wall structure is electrically connected to the first pads; and
a plurality of light emitting elements, disposed on the pad groups, respectively.

14. The display panel of claim 13, wherein the array substrate further comprises:
a signal transmission layer, disposed between the substrate and the pad groups, and electrically connected to the second pads; and
a cushion layer, disposed between the substrate and the first retaining wall structure, and overlapping the first retaining wall structure in a normal line of the substrate, wherein the cushion layer is electrically connected to the first pads.

15. The display panel of claim 14, wherein the second voltage is an operating voltage.

16. The display panel of claim 15, wherein the signal transmission layer provides the operating voltage to the second pads.

17. The display panel of claim 13, wherein the first voltage is a reference voltage.

18. The display panel of claim 17, wherein the reference voltage is a ground voltage.
